(19) United States
(12) Patent Application Publication
(10) Pub. No.: US 2005/0250019 A1
(43) Pub. Date: Nov. 10, 2005

(54) Mask device for photolithography and application thereof

(75) Inventor: Benjamin Szu-Min Lin, Hsin-Chu City (TW)

Correspondence Address: GENESIS/GENUS LAW GROUP, 12760 HIGH BLUFF DRIVE, SUITE 300, SAN DIEGO, CA, 92130, US

(73) Assignee: UNITED MICROELECTRONICS CORP., Hsin-Chu City (TW)

(21) Appl. No.: 10/837,638

(22) Filed: May 4, 2004

(51) Int. Cl. G03C 5/00; G21K 5/00; G03F 9/00

(52) U.S. Cl. 430/5; 378/35; 430/311; 430/312; 430/313

(57) ABSTRACT

A mask device includes a single layer of reflection mask on a transparent substrate to simply the growth fabricating of the reflection mask, therefore, using single layer of reflection mask can easier control the defect. Furthermore, a pattern-transferring method for a photolithography process is to utilize the incident exposing radiation with a grazing incident angle to illuminate the photolithography mask, such that the pattern can be transferred onto the wafer clearly, and the resolution of the photolithography would be improved.

### BACKGROUND OF THE INVENTION

1. Field of the Invention

The present invention generally relates to a photolithography mask device and the application thereof, and more particular to the photolithography mask device and the application thereof in which a photolithography mask device has a single layer of reflection mask with grazing angle incident exposing radiation.

2. Description of the Prior Art

Semiconductor devices such as, for example, transistors in semiconductor components are manufactured using lithographic techniques. It is difficult to utilize conventional lithographic techniques to manufacture features with dimensions of less than 180 nanometers (nm). Accordingly, new lithographic techniques have been developed to more reliably manufacture sub-quartermicron features. As an example, Extreme Ultra-Violet Lithography (EUVL) can be used to manufacture features with dimensions of less than approximately 0.25 microns.

EUVL uses extreme ultra-violet radiation having a wavelength in the range of 4 to 25 nm to carry out projection imaging. EUVL masks are reflective in nature and are not transmissive like masks for other lithographic technologies, such as conventional optical photolithography, Scattering with Angular Limitation Projection Electron beam Lithography (SCALPEL) or X-Ray Lithography (XRL). EUVL masks include a patterned EUV radiation absorber on top of a multi-layered film that is reflective at EUV wavelengths.

Radiation absorbers in EUVL masks have been fabricated using a two-layer process that involves a repair buffer layer of silicon dioxide and a radiation absorbing layer of aluminum-copper, titanium nitride, or the like. One problem with this two-layer process is the difficulty in patterning the repair buffer layer without damaging the underlying reflective multi-layered film. The buffer layer can be patterned with a reactive ion etching technique, but a high etch selectivity to the underlying multi-layered film is difficult to achieve. A wet etch to pattern the buffer layer can result in an undercutting of the buffer layer beneath the patterned absorber layer, and this undercutting produces other problems.

Accordingly, a need exists for an improved method of manufacturing a semiconductor component having sub-micron features. If an EUVL process is used in the manufacturing method, the EUVL masks should be substantially defect free, and the peak reflectivity and band-pass at the EUV wavelengths should remain unchanged before and after the patterning of the radiation-absorbing layer.

Referring to FIG. 1A, which represents the conventional photolithography process, utilizes the normal EUV radiation as the incident exposing radiation to illuminate the reflection mask. The EUV exposing radiation is one of the next candidates for advanced lithography. The conventional process is provided a transparent substrate 100; and a multilayer of reflection mask 102 is formed on the transparent substrate 100. Then, the capping layer 104 is formed on the multilayer of reflection mask 102. After capping layer 104 is formed, the buffer layer 106 is formed on the capping layer 104. Next, an absorber layer 108 is formed on the buffer layer 106.

Next, a photoresist layer (not shown in FIG. 1A) is formed on the absorber layer 108 to define a pattern on the surface of the absorber layer 108. Then, referring to FIG. 1B, an etching process is performed to form an opening 110 within the absorber layer 108 and buffer layer 106, and portion of surface 112 of the capping layer 104 being exposed.

Then, an incident exposing radiation 200 with normal incident angle about 85 degrees illuminated onto the surface of the absorber layer 108 to transfer a pattern to the wafer (not shown).

The exposing radiation 200, EUV radiation with the wavelength is about 13.4 nm, and the energy is about 92.54 eV, used to illuminate the multilayer of reflection mask (Mo/Si) 102 with more than 40 period layers at normal incident angle.

The normal incident exposing radiation 200 illuminates to the multilayer of reflection mask 102 such as Mo/Si with more than 40 periods. For fabricating integrated circuit with 0.1 μm size features, the incident exposing radiation 200 in the wavelength range referred to as EUV exposing radiation has been proposed.

As FIG. 1B, the absorber layer 108 absorbs or scatters the portion partial of the incident exposing radiation 200 to result the absorbed radiation or scattered radiation 200a. Thus, the surface 114 of absorber layer 108 absorbed or scattered the incident exposing radiation 200, such that the pattern is not transfer onto the wafer by incident exposing radiation 200. Thus, there is not feature on the wafer. Thus, the surface 114 of the absorber layer 108 can define as zero, “0”. Otherwise, other partial portion of the incident exposing radiation 200 is illuminated to the exposed surface 112 of capping layer 104. The exposed surface 112 of the capping layer 104 will reflect the partial portion of the incident exposing radiation 200 as the reflected radiation 200b. Thus, the surface 112 of capping layer 104 reflected the incident exposing radiation 200, such that the pattern can transfer onto the wafer by incident exposing radiation 200. Therefore, there is a feature on the wafer. Thus, the surface 112 of the capping layer 104 can define as zero, “0”.

However, it is hard to grow or form a multiplayer masks with smooth and defect-free surfaces.

### SUMMARY OF THE INVENTION

It is one of the objects of this invention to provide a mask device with a single layer of reflection mask and the application thereof to replace the multilayer of reflection mask to simply the fabrication process.

It is a further object of this invention to provide a mask device with a single layer of reflection mask with reflectivity as higher as the conventional multilayer of reflection mask used for photolithography process to increase the resolution of the photolithography.

It is still another object of this invention to provide a photolithography process using an incident exposing radiation with incident grazing angle to illuminate the single layer of reflection mask to reduce the defect during the exposing radiation process.

It is yet another object of this invention that is to provide a photolithography process using an incident exposing radiation with an incident grazing angle to illuminate the single layer of reflection mask to transfer the pattern with a smooth surface region and a rough surface region clearly onto the wafer.

It is an object of this invention to provide a single layer of reflection mask structure and the formation thereof easier to control the defect then the conventional multilayer structure mask.

According to above the objects, the present invention provides a method and a structure for photolithography mask to improve the resolution of photolithography process. The steps of the method include providing a substrate, and a single layer of reflection mask is formed on the substrate. Then, a photoresist layer is formed on the surface of the single layer of reflection mask to define a pattern. The pattern with a rough surface region and a smooth surface region is formed on/in the surface of the single layer of reflection mask.

Next, an incident exposing radiation with an incident grazing angle is used to illuminate the surface of the single layer of reflection mask to result the partial portion of the incident exposing radiation is absorbed by the rough surface region, and other portion of incident exposing radiation is reflected by the smooth surface region. Thus, the rough surface region absorbed or scattered the incident exposing radiation, such that the pattern cannot transfer onto the wafer by incident exposing radiation. Thus, the rough surface region can define as zero, “0”. Otherwise, the smooth surface region reflected the incident exposing radiation, such that the pattern can transfer onto the wafer clearly by incident exposing radiation. Thus, the smooth surface region can define as “1”. The advantage of the present invention is that the pattern would be presented clearly onto the wafer.

The structure of the photolithography mask is that a transparent substrate is provided, and a single layer of reflection mask with a defined pattern is on the transparent substrate. The single layer of reflection mask has a reflectivity as higher as the conventional multilayer of reflection mask, and the growth fabrication of the single layer of reflection mask is easier than the conventional multilayer of reflection mask. Furthermore, the defined pattern with a rough surface region is used to absorb or scatter the incident exposing radiation. Thus, the defined pattern onto wafer will present the dark area. The defined pattern further comprises a smooth surface region that is used to reflect the incident exposing radiation. Thus, the pattern onto the wafer will present the bright area.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A to FIG. 1B are schematic representation the conventional photolithography technology for normal extreme ultraviolet exposing radiation is illuminated on the surface of multilayer of reflection mask; and

FIG. 2A to FIG. 2C are a schematic representation the photolithography process with using incident grazing angle exposing radiation to illuminate a single layer of reflection mask in accordance with a method and structure disclosed herein; and

FIG. 3 is a chart illustrates the relationship of incident angle of radiation 20, roughness of reflection mask and reflectivity thereof in accordance with the method and structure disclosed herein.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

According to conventional photolithography process utilized normal incident exposing radiation to illuminate multilayer of reflection mask will cause the defect on the multilayer of the reflection mask. The growth of the conventional multilayer of reflection mask is very difficult when using the extreme ultraviolet exposing incident radiation. Thus, the present invention provides a structure and a method for forming a photolithography mask to simply the photolithography fabrication process, and the defect also can be reduced.

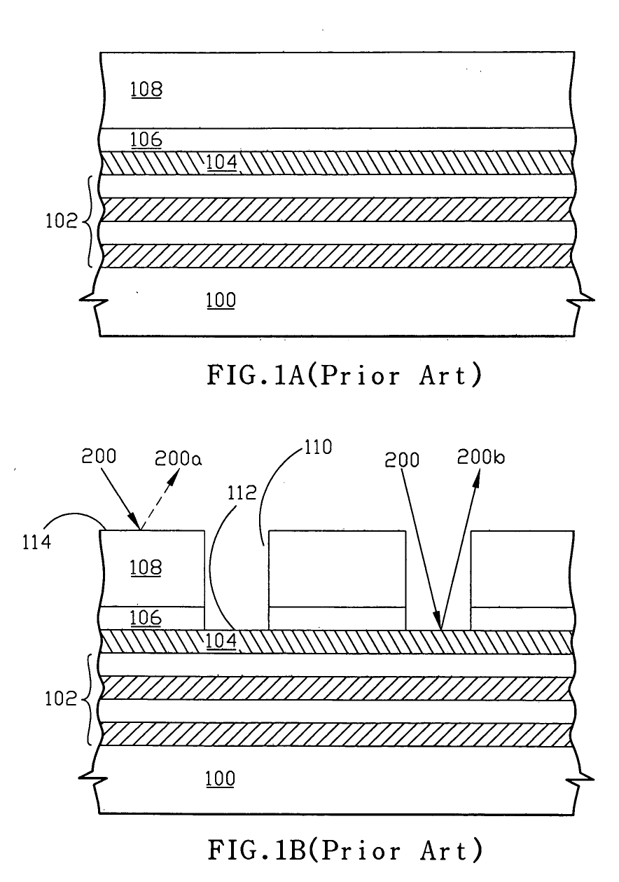

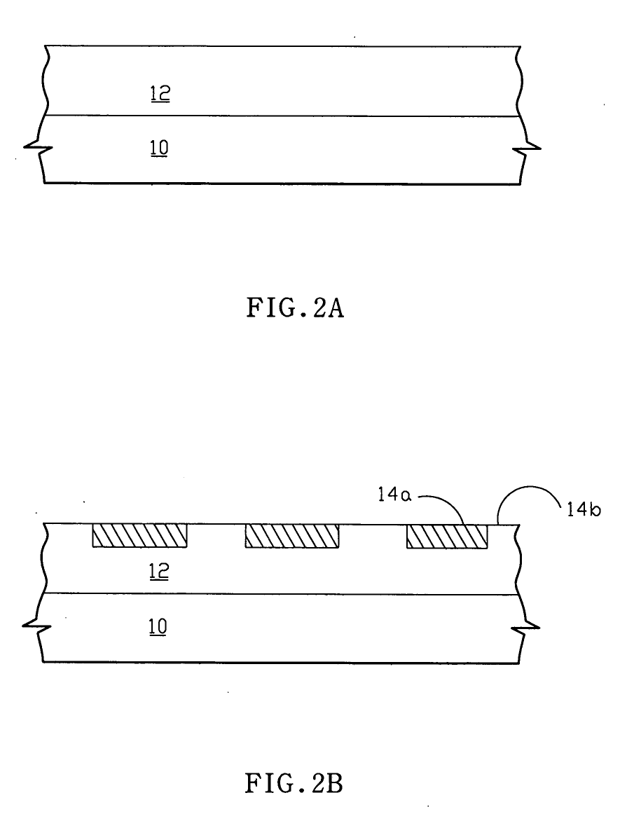

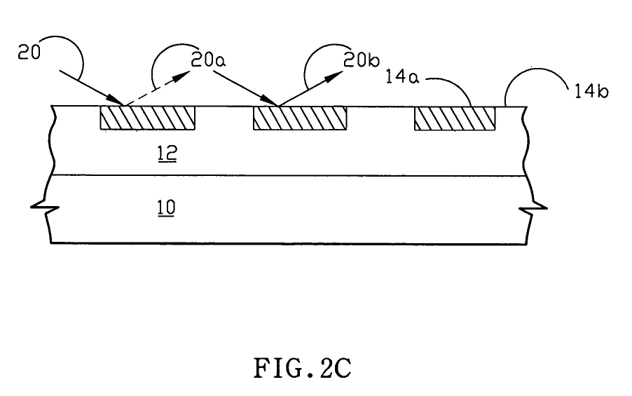

Referring to FIG. 2A to FIG. 2B, a transparent substrate 10 is provided, and a single layer of reflection mask 12 with a defined pattern therein or thereon on the transparent substrate 10. The single layer of reflection mask 12, such as a material containing Mo, has a reflectivity as higher as the conventional multilayer of the reflection mask 102 in FIG. 1A. The growth of the single layer of reflection mask 12 is simple than the conventional multilayer of reflection mask 102, and the defects of the single layer of reflection mask 12 is easier controlled than the conventional multilayer of reflection mask 102. Thus, the single layer of reflection mask 12 can replace the conventional multilayer of reflection mask 102.

As shown in FIG. 2C, the defined pattern includes a rough surface region 14a and a smooth surface region 14b. The rough surface region 14a can absorb or scatter the incident exposing radiation 20 as the absorbed or scattered radiation 20a, such that the pattern with the rough surface region 14a cannot transfer onto the wafer (not shown). Therefore, there will be a dark area on the wafer. Thus, the rough surface region 14a can define as zero, “0”. On the other hand, the smooth surface region 14b can reflect the incident exposing radiation 20 as the reflected radiation 20b, such that the defined pattern with the smooth surface region 14b can transfer onto the wafer. Therefore, there will be a bright area on the wafer. Thus, the smooth surface region 14b can define as “1”.

The advantage of present invention is to use a single layer of reflection mask 12 with a reflectivity as higher as the conventional multilayer of reflection mask 102. Thus, the single layer of reflection mask 12 can replace the conventional multilayer of reflection mask 102, such that the growth fabricating can be simplified, and the defects are easier to control.

Moreover, it is not necessary for the single layer of reflection mask 12 in the embodiment to include a capping layer 104, a buffer layer 106, and an absorber layer 108 in FIG. 1A as the conventional photolithography mask structure. The patterned single layer of reflection mask 12 can be used as the patterned mask to be capable of absorbing and the reflecting the incident exposing radiation 20 when illuminated. Thus, the fabrication process is simpler than the conventional photolithography mask structure.

Moreover, the present invention provides a method for forming a photolithography mask structure for photolithography process to increase the resolution of photolithography. As shown in FIG. 2A, the steps of the method include providing a transparent substrate 10, such as quartz. A single layer of reflection mask 12, such as Mo (Molybdenum) is formed on the transparent substrate 10. The single layer of reflection mask 12 has a reflectivity as higher as the conventional multilayer of reflection mask 102 (as shown in FIG. 1A). The growth of single layer of reflection mask 12 is also simpler than the conventional multilayer of reflection mask 102, such that the defects will be easier controlled. Thus, the single layer of reflection mask 12 can replace the conventional multilayer of reflection mask 102 as the conventional process disclosed to simplify the fabrication process.

Then, referring to FIG. 2B, a photolithography process is performed to the single layer of reflection mask 12 to define a pattern on the surface of the single layer of reflection mask 12, wherein the pattern is desired by the user requested. The, defined pattern with a rough surface region 14a and a smooth surface region 14b therein or thereon is on the surface of single layer of reflection mask 12.

In FIG. 2C, when the incident exposing radiation 20 such as EUV (extreme ultraviolet) radiation with a wavelength in the range of 10 to 14 nanometers (nm) to carry out projection imaging, and with an incident grazing angle is illuminated to the rough surface region 14a and the smooth surface region 14b of the patterned single layer of reflection mask 12, the rough surface region 14a will absorb or scatter the incident exposing radiation 20, and the smooth surface region 14b will reflect the incident exposing radiation 20, respectively. When the rough surface region 14a absorbed or scattered the incident exposing radiation, the transferred pattern on the wafer will present a dark area, such that the rough surface region 14a could be set as zero “0”, which expresses that is no feature on the wafer.

If the incident exposing radiation 20 is illuminated to the smooth surface region 14b of the patterned single layer of reflection mask 12, the smooth surface region 14b will reflect the incident exposing radiation 20. Thus, the pattern will present the bright area on the wafer after the pattern transferring onto the wafer. Thus, the smooth surface region 14b could be set as “1”, which expresses that is a feature on the wafer.

In one embodiment, the incident angle of the incident exposing radiation 20 is a grazing angle, and the angle degree range is about less than 20 degree. In order to keeps the incident angle between the incident exposing radiation 20 and the wafer is invariable, the incidence angle between the incidents exposing radiation 20 to the single layer of reflection mask 12 is shifted. Thus, the incident angle degree of the incident exposing radiation 20 to the single layer of reflection mask 12 is shifted to be a grazing angle, which is smaller than the conventional photolithography process.

When the incident exposing radiation 20 is illuminated to the patterned single layer of reflection mask 12, the pattern can transfer onto the wafer. Thus, the feature can present the bright area and the dark area clearly on the wafer. Therefore, the resolution of the pattern can be improved, and the defect can be easily to control by using the single layer of reflection mask 12, and incident exposing radiation 20 with grazing incident angle.

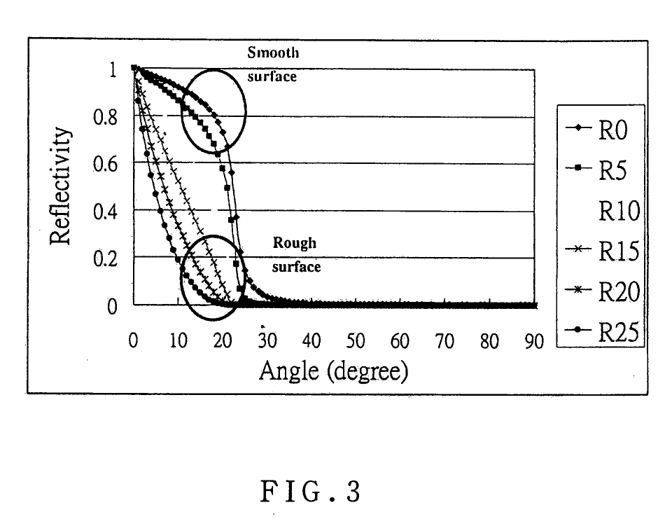

FIG. 3 is a chart illustrating the relationship of incident angle of exposing radiation 20, roughness of reflection mask 12 and reflectivity thereof. Shown in FIG. 3, the respective reflectivity of reflection mask 12 with different roughness is explicitly distinguishable on condition that the incident angle of exposing radiation 20 is less than 30 degree, preferably less than 20 degree. On the other hand, it is not easy to read the respective reflectivity when the incident angle of exposing radiation 20 is over 40 degree. Accordingly, a grazing angle applied on the incidence of the exposing radiation onto the single layer of reflection mask is capable of possessing different features accepted by a destination wafer.

Although specific embodiments have been illustrated and described, it will be obvious to those skilled in the art that various modifications may be made without departing from what is intended to be limited solely by the appended claims.

1. A mask device comprising:
a transparent substrate; and
a patterned single layer of reflection mask with a rough surface region and a smooth surface region thereon and therein on said transparent substrate.

2. The mask device according to claim 1, wherein said the material of said transparent substrate is quartz.

3. The mask device according to claim 1, wherein the material of said single layer of reflection mask is Mo (molybdenum).

4. The mask device according to claim 1, wherein said patterned single layer of reflection mask is formed by a photolithography process.

5. A method for forming a semiconductor device, said method comprising:
providing a transparent substrate;
forming a single layer of reflection mask on said transparent substrate;
performing a photolithography process to define a pattern on said single layer of reflection mask; and
illuminating an incident exposing radiation to a surface of said single layer of reflection mask to transfer said pattern onto a wafer.

6. The method according to claim 5, wherein the material of said transparent substrate is quartz.

7. The method according to claim 5, wherein the material of said single layer of reflection mask is Mo (molybdenum).

8. The method according to claim 5, wherein said incident exposing radiation is extreme ultraviolet (EUV).

9. The method according to claim 5, wherein said pattern comprises a rough surface region and a smooth surface region.

10. A method for fabricating a semiconductor device, said method comprising:
providing a transparent substrate;
forming a single layer of reflection mask on said transparent substrate;
performing a photolithography process to define a pattern with a rough surface region and a smooth surface region on said single layer of reflection mask; and
illuminating an incident exposing radiation with an incident grazing angle to said pattern on said single layer of reflection mask to transfer said pattern onto a wafer.

11. The method according to claim 10, wherein the material of said transparent substrate is quartz.

12. The method according to claim 10, wherein the material of said single layer of reflection mask is Mo (molybdenum).

13. The method according to claim 10, wherein said incident exposing radiation is extreme ultraviolet (EUV).

14. The method according to claim 10, wherein said incident grazing angle is about less than 20 degree.

15. A method of pattern transferring applied on lithography process, said method of pattern transferring comprising:
providing a mask device with a single layer of reflection mask; and
utilizing an incident exposing radiation with a grazing angle incident onto said mask device, wherein said grazing angle is less than 20 degree corresponding to said single layer of reflection mask.

16. The method of pattern transferring according to claim 15, wherein said single layer of reflection mask comprises a smooth region and a rough region thereon.

17. The method of pattern transferring according to claim 15, wherein said incident exposing radiation is extreme ultraviolet.
